(19) United States
(12) Patent Application Publication
(10) Pub. No.: US 2011/0194831 A1
(43) Pub. Date: Aug. 11, 2011

(54) DEVICE AND METHOD FOR CONTROLLING CLOCK RECOVERY

(76) Inventor: Mu-Hsien Hsu, Tainan County (TW)

(21) Appl. No.: 12/701,627

(22) Filed: Feb. 8, 2010

(51) Int. Cl. H04N 7/087; H03L 7/06; H04N 5/04; H04N 5/931; H04N 5/932

(52) U.S. Cl. 386/204; 327/156; 348/500; 348/E05.009; 386/E05.003

(57) ABSTRACT

A clock recovery device includes a PLL circuit and a tuning circuit. The PLL circuit includes a first frequency divider, a second frequency divider, and a clock recovery unit. The first frequency divider divides a first frequency of the input clock by a first divisor to generate a reference signal. The second frequency divider divides a second frequency of the output clock by a second divisor to generate a feedback signal. The clock recovery unit is coupled to the first frequency divider and the second frequency divider, for re-building and providing the output clock according to the reference signal and the feedback signal. The tuning circuit is coupled to the PLL circuit, for tuning at least one of the first divisor and the second divisor of the PLL circuit according to a buffer status information of a data buffer.

### BACKGROUND OF THE INVENTION

1. Field of the Invention

The present invention relates to a clock recovery device and a related method for controlling clock recovery, and more particularly, to a device and a method for controlling clock recovery by tuning divisor(s) of a PLL circuit according to a buffer status information of a data buffer in a video processing system.

2. Description of the Prior Art

Please refer to FIG. 1. FIG. 1 is a diagram of a conventional PLL circuit 100 according to the prior art. The conventional PLL circuit 100 includes a first frequency divider 110, a clock recovery unit 120, and a second frequency divider 130. The PLL circuit 100 is used for re-building and providing an output clock CKout according to an input clock CKin. The first frequency divider 110 divides a first frequency f1 of the input clock CKin by a first divisor N to generate a reference signal S_{REF}. The second frequency divider 130 divides a second frequency f2 of the output clock CKout by a second divisor M to generate a feedback signal S_{FB}. Finally, the clock recovery unit 120, coupled to the first frequency divider 110 and the second frequency divider 120, re-builds and provides the output clock CKout according to the reference signal S_{REF} and the feedback signal S_{FB}.

The PLL circuit 100 maybe used for performing clock recovery in serializer/deserializer(SERDES) design. However, a data width of the values M and N in SERDES is much larger than other applications. For example, a data width of 20-bits is required for HDMI standard, and a data-width of 24-bits is required for DisplayPort standard. For this reason, it makes the clock stable time of the PLL circuit 100 much longer, and the size of the PLL circuit 100 much bigger than other designs with a smaller data width.

Hence, how to provide a clock recovery device with a small size and a faster clock stable time have become an important topic of this field, especially in the SERDES design.

### SUMMARY OF THE INVENTION

It is one of the objectives of the claimed invention to provide a clock recovery device, a video processing system, and a related method for controlling clock recovery to solve the above-mentioned problems.

According to one embodiment, a clock recovery device is provided. The clock recovery device includes a phase locked loop (PLL) circuit and a tuning circuit. The PLL circuit includes a first frequency divider, a second frequency divider, and a clock recovery unit. The first frequency divider divides a first frequency of the input clock by a first divisor to generate a reference signal. The second frequency divider divides a second frequency of the output clock by a second divisor to generate a feedback signal. The clock recovery unit is coupled to the first frequency divider and the second frequency divider, for re-building and providing the output clock according to the reference signal and the feedback signal. The tuning circuit is coupled to the PLL circuit, for tuning at least one of the first divisor and the second divisor of the PLL circuit according to a buffer status information of a data buffer.

According to another embodiment, a video processing system is provided. The video processing system includes a data buffer, a clock recovery device, and a video processor. The data buffer receives an input video data so as to output an output video data, and provides a buffer status information of the data buffer, wherein the input video data is written into the data buffer according to an input clock, and the output video data is read from the data buffer according to an output clock. The clock recovery device includes a phase locked loop (PLL) circuit and a tuning circuit. The PLL circuit includes a first frequency divider, a second frequency divider, and a clock recovery unit. The first frequency divider divides a first frequency of the input clock by a first divisor to generate a reference signal. The second frequency divider divides a second frequency of the output clock by a second divisor to generate a feedback signal. The clock recovery unit is coupled to the first frequency divider and the second frequency divider, for re-building and providing the output clock according to the reference signal and the feedback signal. The tuning circuit is coupled to the PLL circuit, for tuning at least one of the first divisor and the second divisor of the PLL circuit according to the buffer status information. The video processor is coupled to the data buffer and the clock recovery device, for processing the output video data, wherein the video processor is configured to operate in the output clock.

According to another embodiment, a method for controlling clock recovery is provided. The method includes the steps of: receiving an input clock, and dividing a first frequency of the input clock by a first divisor to generate a reference signal; dividing a second frequency of an output clock by a second divisor to generate a feedback signal; tuning at least one of the first divisor and the second divisor according to a buffer status information of a data buffer; and re-building and providing the output clock according to the reference signal and the feedback signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a conventional PLL circuit according to the prior art.

FIG. 2 is a block diagram of a clock recovery device according to an embodiment of the present invention.

FIG. 3 is a block diagram of a video processing system according to an embodiment of the present invention.

FIG. 4 is a comparison diagram illustrating the resultant curves of the output clocks shown in FIG. 1 and FIG. 2.

FIG. 5 is a flowchart illustrating a method for controlling clock recovery according to an exemplary embodiment of the present invention.

### DETAILED DESCRIPTION

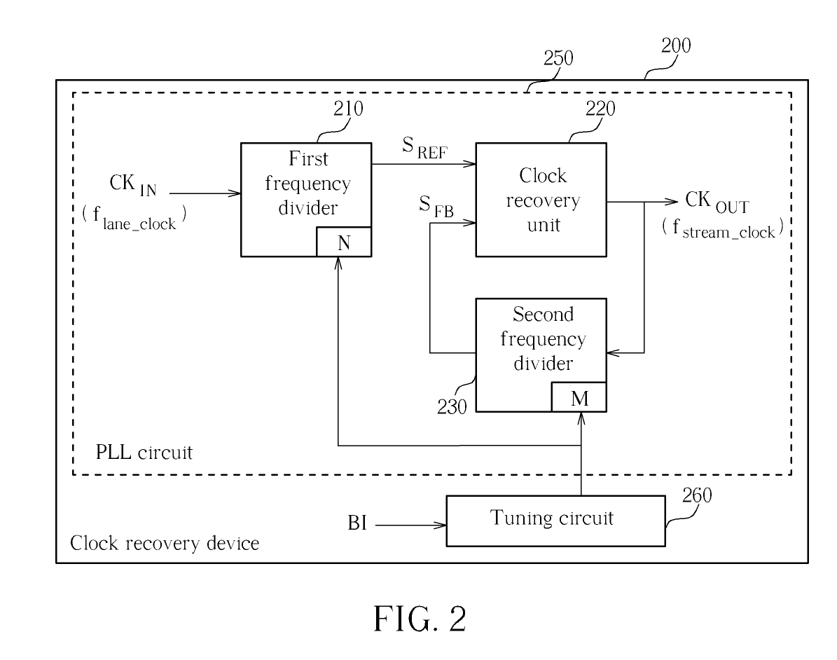

Please refer to FIG. 2. FIG. 2 is a block diagram of a clock recovery device 200 according to an embodiment of the present invention. As shown in FIG. 2, the clock recovery device 200 includes a PLL circuit 250 and a tuning circuit 260. The PLL circuit 250 includes a first frequency divider 210, a second frequency divider 230, and a clock recovery unit 220. The clock recovery device 200 re-builds and provides an output clock CKout according to an input clock CKin. In this embodiment, the clock recovery device 200 is applied to a serializer/deserializer of a video processing system, and thus the input clock CKin is a lane clock and the output clock CKout is a stream clock. But this is not meant to be a limitation of the present invention, those skilled in the art should appreciate that the clock recovery device 200 can be applied to other designs, which also belongs to the scope of the present invention.

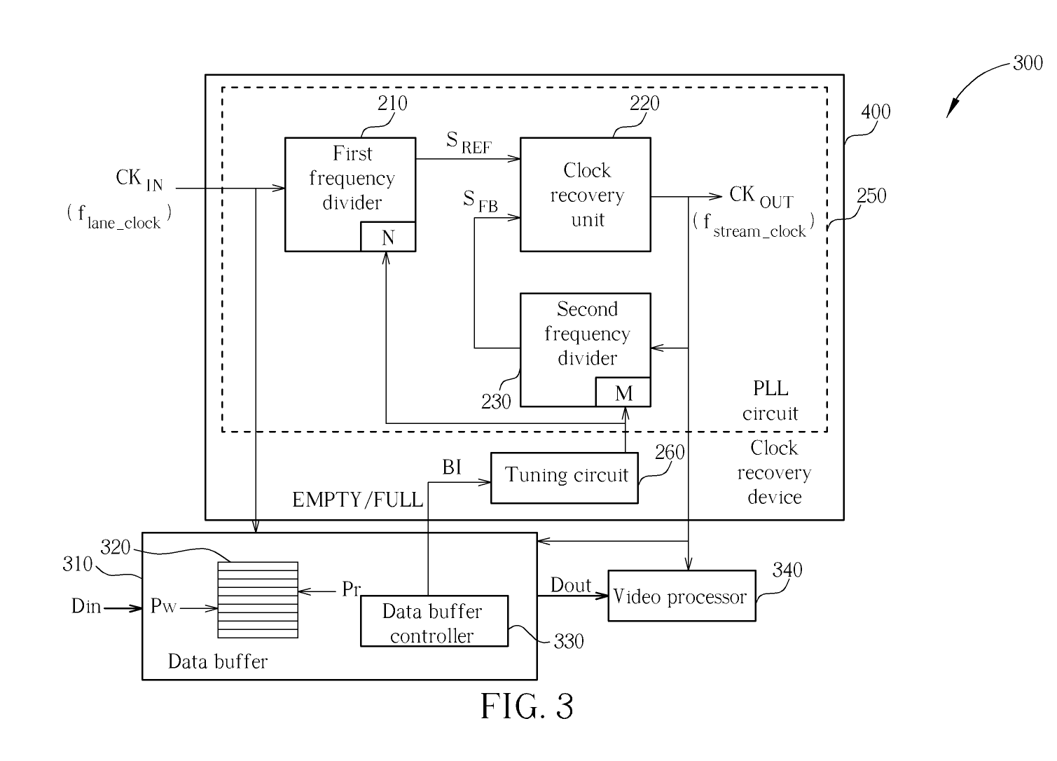

As shown in FIG. 2, the first frequency divider 210 divides a first frequency flane_clock of the input clock CKin by a first divisor N to generate a reference signal S_{REF}. The second frequency divider 230 divides a second frequency fstream_clock of the output clock CKout by a second divisor M to generate a feedback signal S_{FB}. After that, the clock recovery unit 220 is coupled to the first frequency divider 210 and the second frequency divider 220, for re-building and providing the output clock CKout according to the reference signal S_{REF} and the feedback signal S_{FB}. In addition, the tuning circuit 260 is coupled to the PLL circuit 250. In this embodiment, the tuning circuit 260 is coupled to the first frequency divider 210 and the second frequency divider 220. Be noted that the tuning circuit 260 is capable of tuning at least one of the first divisor N and the second divisor M of the PLL circuit 250 according to a buffer status information BI of a data buffer (please also refer to FIG. 3).

From FIG. 2, we can see that the first frequency flane_clock of the input clock CKin, the second frequency fstream_clock of the output clock CKout, the first divisor N, and the second divisor M conform to the following equation:

fₛₜᵣₑₐₘ_{_{—}}_{clock}/fₗₐₙₑ_{_{—}}_{clock}=M/N (1).

Typically, the first frequency flane_clock of the input clock CKin is a fixed value, and the second frequency fstream_clock of the output clock Ckout is a variation value which is related to its resolution and can be obtained from CEA standards (Consumer Electronics Association standards). The Displayport standard with a resolution of 720P is cited as an illustration, the first frequency flane_clock of the input clock CKin is equal to 162 MHz and the second frequency fstream_clock of the output clock Ckout is equal to 74 MHz. As can be known from the abovementioned equation (1), the second frequency fstream_clock of the output clock Ckout can be determined depending on the first divisor N and the second divisor M.

What calls for special attention is that the first divisor N and the second divisor M can be dynamically tuned via the tuning circuit 260 simultaneously or at different times. That is to say, in one embodiment, the tuning circuit 260 may tune the first divisor N in order to adjust the second frequency fstream_clock; in another embodiment, the tuning circuit 260 may tune the second divisor M in order to adjust the second frequency fstream_clock; in still another embodiment, the tuning circuit 260 may tune a ratio of the second divisor M to the first divisor N (i.e., M/N) in order to adjust the second frequency fstream_clock. Those skilled in the art should appreciate that various modifications of the tuning circuit 260 may be made without departing from the spirit of the present invention, and should also belong to the scope of the present invention.

Please refer to FIG. 3. FIG. 3 is a block diagram of a video processing system 300 according to an embodiment of the present invention. As shown in FIG. 3, the video processing system 300 includes a data buffer 310, a clock recovery device 400, and a video processor 340. Since the architecture of the clock recovery device 400 is the same as the clock recovery device 200 shown in FIG. 2, further description is omitted here for brevity. The data buffer 310 receives an input video data Din so as to output an output video data Dout to the video processor 340. In addition, the data buffer 310 provides a buffer status information BI (at least including an almost empty signal EMPTY and an almost full signal FULL) to the tuning circuit 260 of the clock recovery device 400. In this embodiment, the output clock CKout is a read clock of the data buffer 310, and the input clock CKin is a write clock of the data buffer 310; that is to say, the input video data Din is written into the data buffer 310 according to the input clock CKin, and the output video data Dout is read from the data buffer 340 according to the output clock Ckout. In general, the frequency of the input video data Din writing into the data buffer 310 does not excel the first frequency flane_clock of the input clock CKin for the reason that the dummy data in the input video data Din is dropped from writing into the data buffer 310. After that, the video processor 340 is coupled to the data buffer 310 and the clock recovery device 400, for processing the output video data Dout. Please note that the video processor 340 is configured to operate in the output clock Ckout.

Please note that the buffer status information BI indicates whether the second frequency fstream_clock of the output clock CKout is slower or faster than a normal frequency of a normal output clock, such as the frequency of the input video data Din writing into the data buffer 310 (e.g., 74 MHz for DisplayPort standard with a resolution of 720P). In this embodiment, the data buffer 310 includes a first-in first-out (FIFO) 320, a write pointer Pw, a read pointer Pr, and a data buffer controller 330. The FIFO 320 records the input video data Din so as to output the output video data Dout. Additionally, the write pointer Pw indicates a write address of the FIFO 320 in which the input video data Din is recorded; while the read pointer Pr indicates a read address of the FIFO 320 in which the output video data Dout is outputted. The data buffer controller 330 is coupled to the FIFO 320, for setting the buffer status information BI (at least including the almost empty signal EMPTY and the almost full signal FULL) according to the write pointer Pw and the read pointer Pr.

As an illustration, when the read pointer Pr reaches to the write pointer Pw, the data buffer controller 330 triggers the almost empty signal EMPTY as the buffer status information BI. Under this condition, the tuning circuit 260 tunes at least one of the first divisor N and the second divisor M in order to decrease a ratio M/N of the second divisor M to the first divisor N. When the write pointer Pw reaches to the read pointer Pr, the data buffer controller 330 triggers the almost full signal FULL as the buffer status information BI. Under this condition, the tuning circuit 260 tunes at least one of the first divisor N and the second divisor M in order to increase the ratio M/N of the second divisor M to the first divisor N. Additionally, when another condition does not meet above-mentioned conditions (almost full and almost empty), the tuning circuit 260 may trigger a normal signal NORMAL (not shown) or no signal, as the buffer status information BI for maintaining the first divisor N and the second divisor M.

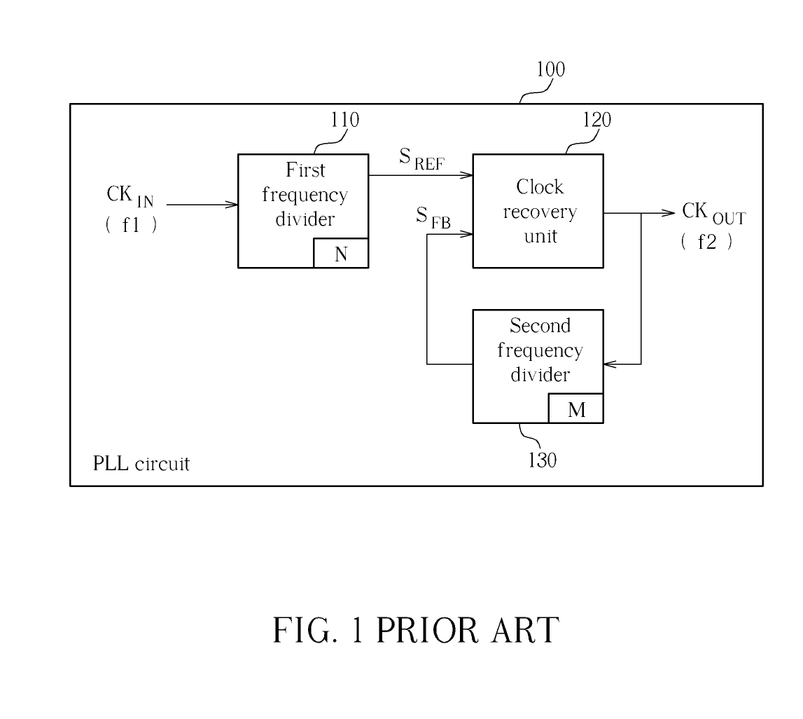

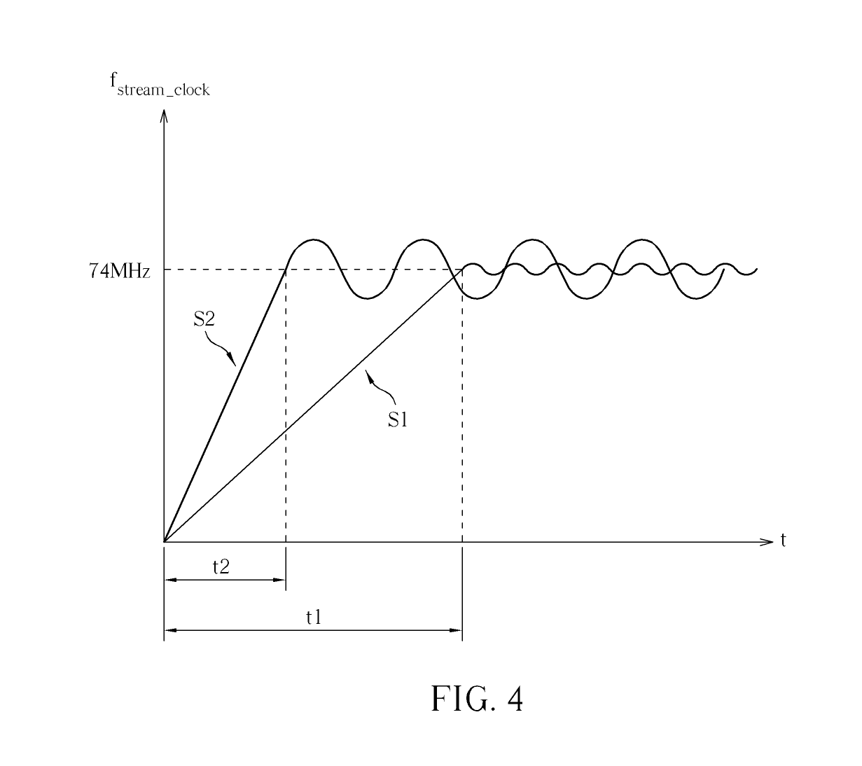

Please refer to FIG. 4. FIG. 4 is a comparison diagram illustrating the resultant curves of the output clocks CKout shown in FIG. 1 and FIG. 2. Herein a first curve S1 represents the output clock CKout of the conventional PLL circuit 100 shown in FIG. 1, and the second curve S2 represents the output clock CKout of the clock recovery device 200 shown in FIG. 2. As can be seen from FIG. 4, the clock stable time t2 of the second curve S2 disclosed in the present invention is much faster than the clock stable time t1 of the first curve S1.

In short, based on the buffer status information BI (at least including the almost empty signal EMPTY or the almost full signal FULL), we can easily know whether the output clock CKout is slower or faster than a normal output clock. By adopting the buffer status information BI to fine tune the first divisor N and/or the second divisor M, we can design the PLL circuit which has a small data width of the M and N values to replace the original big one (e.g., the conventional PLL circuit 100 shown in FIG. 1). Therefore, a faster clock stable time of the clock recovery device and a smaller size for designing the clock recovery device can be achieved, and thus the whole manufacturing cost can be saved.

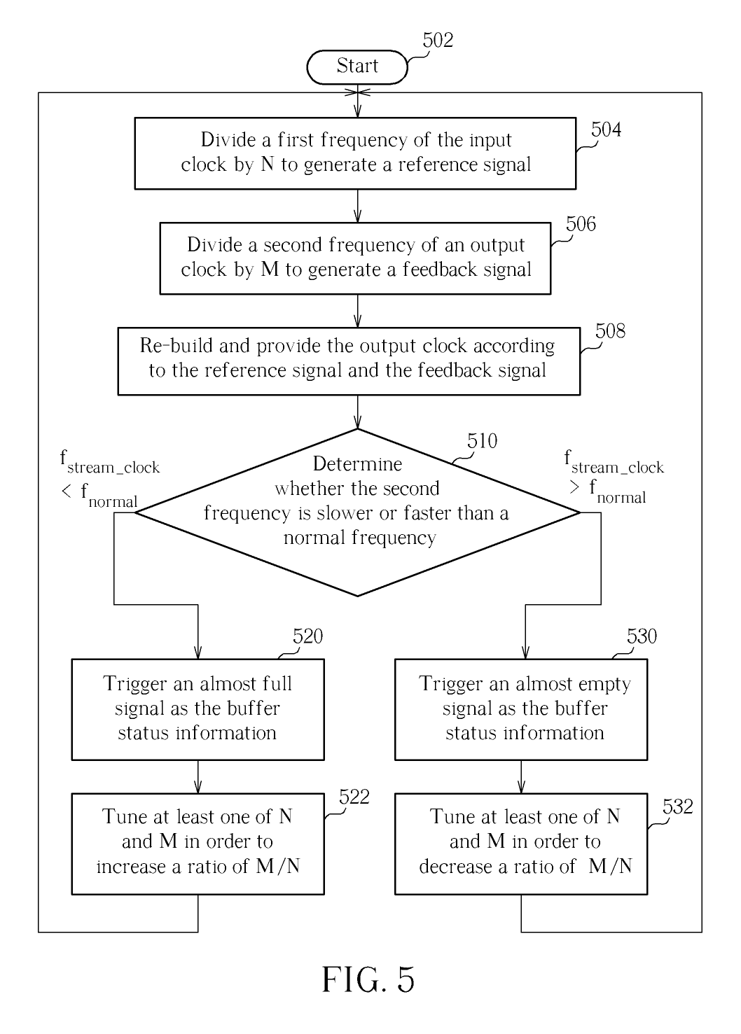

Please refer to FIG. 5. FIG. 5 is a flowchart illustrating a method for controlling clock recovery according to an exemplary embodiment of the present invention. Please note that the following steps are not limited to be performed according to the exact sequence shown in FIG. 5 if a roughly identical result can be obtained. The method includes, but is not limited to, the following steps:

Step 502: Start.

Step 504: Receive an input clock, and divide a first frequency of the input clock by a first divisor to generate a reference signal.

Step 506: Divide a second frequency of an output clock by a second divisor to generate a feedback signal.

Step 508: Re-build and provide the output clock according to the reference signal and the feedback signal.

Step 510: Determine whether the second frequency of the output clock is slower or faster than a normal frequency of a normal output clock. When the second frequency is slower than the normal frequency, go to the Step 520; otherwise, go to the Step 530.

Step 520: When the second frequency is slower than the normal frequency, trigger an almost full signal as the buffer status information.

Step 522: Tune at least one of the first divisor and the second divisor in order to increase a ratio of the second divisor to the first divisor.

Step 530: When the second frequency is faster than the normal frequency, trigger an almost empty signal as the buffer status information.

Step 532: Tune at least one of the first divisor and the second divisor in order to decrease a ratio of the second divisor to the first divisor.

How each element operates can be known by collocating the steps shown in FIG. 5 together with the elements shown in FIG. 2 or FIG. 3, and further description is omitted here for brevity. Be noted that the step 504 is executed by the first frequency divider 210, the step 506 is executed by the second frequency divider 230, the step 510 is indicated from the buffer status information BI, the steps 520 and 530 are executed by the data buffer controller 330, the steps 522 and 532 are executed by the tuning circuit 260, and the step 508 is executed by the clock recovery unit 220.

Please note that, the steps of the abovementioned flowchart are merely a practicable embodiment of the present invention, and in no way should be considered to be limitations of the scope of the present invention. The method can include other intermediate steps or several steps can be merged into a single step without departing from the spirit of the present invention.

The abovementioned embodiments are presented merely for describing the features of the present invention, and in noway should be considered to be limitations of the scope of the present invention. In summary, the present invention provides a clock recovery device, a video processing system and a related method. By making use of the buffer status information BI, the first divisor N and/or the second divisor M can be dynamically adjusted. Therefore, we can design the PLL circuit which has a small data width of the M and N values. Furthermore, a faster clock stable time of the clock recovery device can be achieved, and thus the whole manufacturing cost can be saved.

Those skilled in the art will readily observe that numerous modifications and alterations of the device and method may be made while retaining the teachings of the invention.

What is claimed is:

1. A clock recovery device, comprising:
a phase locked loop (PLL) circuit, for re-building and providing an output clock according to an input clock, the PLL circuit comprising:
a first frequency divider, for dividing a first frequency of the input clock by a first divisor to generate a reference signal;
a second frequency divider, for dividing a second frequency of the output clock by a second divisor to generate a feedback signal; and
a clock recovery unit, coupled to the first frequency divider and the second frequency divider, for re-building and providing the output clock according to the reference signal and the feedback signal; and
a tuning circuit, coupled to the PLL circuit, for tuning at least one of the first divisor and the second divisor of the PLL circuit according to a buffer status information of a data buffer.

2. The clock recovery device of claim 1, wherein the first frequency of the input clock, the second frequency of the output clock, the first divisor, and the second divisor conform to the following equation:
fₛₜᵣₑₐₘ_{_{—}}_{clock}/fₗₐₙₑ_{_{—}}_{clock}=M/N;
wherein fₛₜᵣₑₐₘ_{_{—}}_{clock} represents the second frequency of the output clock, fₗₐₙₑ_{_{—}}_{clock} represents the first frequency of the input clock, M represents the second divisor, and N represents the first divisor.

3. The clock recovery device of claim 1, wherein the input clock and the output clock drive the data buffer.

4. The clock recovery device of claim 3, wherein the buffer status information indicates whether the second frequency of the output clock is slower or faster than a normal frequency of a normal output clock.

5. The clock recovery device of claim 3, wherein the output clock is a read clock of the data buffer; and the input clock is a write clock of the data buffer.

6. The clock recovery device of claim 1, wherein the clock recovery device is applied to a serializer/deserializer of a video processing system; the input clock is a lane clock; and the output clock is a stream clock.

7. A video processing system, comprising:
a data buffer, for receiving an input video data so as to output an output video data, and for providing a buffer status information, wherein the input video data is written into the data buffer according to an input clock, and the output video data is read from the data buffer according to an output clock;
a clock recovery device, comprising:
a PLL circuit, for re-building and providing the output clock according to the input clock, the PLL circuit comprising:
a first frequency divider, for dividing a first frequency of the input clock by a first divisor to generate a reference signal;
a second frequency divider, for dividing a second frequency of the output clock by a second divisor to generate a feedback signal; and
a clock recovery unit, coupled to the first frequency divider and the second frequency divider, for re-building and providing the output clock according to the reference signal and the feedback signal; and
a tuning circuit, coupled to the PLL circuit and the data buffer, for tuning at least one of the first divisor and the second divisor according to the buffer status information; and
a video processor, coupled to the data buffer and the clock recovery device, for processing the output video data, wherein the video processor is configured to operate in the output clock.

8. The video processing system of claim 7, wherein the first frequency of the input clock, the second frequency of the output clock, the first divisor, and the second divisor conform to the following equation:
fₛₜᵣₑₐₘ_{_{—}}_{clock}/fₗₐₙₑ_{_{—}}_{clock}=M/N;
wherein fₛₜᵣₑₐₘ_{_{—}}_{clock} represents the second frequency of the output clock, fₗₐₙₑ_{_{—}}_{clock} represents the first frequency of the input clock, M represents the second divisor, and N represents the first divisor.

9. The video processing system of claim 7, wherein the buffer status information indicates whether the second frequency of the output clock is slower or faster than a normal frequency of a normal output clock.

10. The clock recovery device of claim 7, wherein the output clock is a read clock of the data buffer, and the input clock is a write clock of the data buffer.

11. The video processing system of claim 7, wherein the data buffer comprises:
a first-in first-out (FIFO), for recording the input video data so as to output the output video data;
a write pointer, for indicating a write address of the FIFO in which the input video data is recorded;
a read pointer, for indicating a read address of the FIFO in which the output video data is outputted; and
a data buffer controller, coupled to the FIFO, for setting the buffer status information according to the write pointer and the read pointer.

12. The video processing system of claim 11, wherein when the read pointer reaches to the write pointer, the data buffer controller triggers an almost empty signal as the buffer status information, and the tuning circuit tunes at least one of the first divisor and the second divisor in order to decrease a ratio of the second divisor to the first divisor; and when the write pointer reaches to the read pointer, the data buffer controller triggers an almost full signal as the buffer status information, and the tuning circuit tunes at least one of the first divisor and the second divisor in order to increase the ratio of the second divisor to the first divisor.

13. A method for controlling clock recovery, comprising the steps of:
receiving an input clock, and dividing a first frequency of the input clock by a first divisor to generate a reference signal;
dividing a second frequency of an output clock by a second divisor to generate a feedback signal;
tuning at least one of the first divisor and the second divisor according to a buffer status information of a data buffer; and
re-building and providing the output clock according to the reference signal and the feedback signal.

14. The method of claim 13, wherein the first frequency of the input clock, the second frequency of the output clock, the first divisor, and the second divisor conform to the following equation:
fₛₜᵣₑₐₘ_{_{—}}_{clock}/fₗₐₙₑ_{_{—}}_{clock}=M/N;
wherein fₛₜᵣₑₐₘ_{_{—}}_{clock} represents the second frequency of the output clock, fₗₐₙₑ_{_{—}}_{clock} represents the first frequency of the input clock, M represents the second divisor, and N represents the first divisor.

15. The method of claim 13, wherein the buffer status information indicates whether the second frequency of the output clock is slower or faster than a normal frequency of a normal output clock.

16. The method of claim 13, further comprising the steps of:
receiving an input video data so as to output an output video data, wherein the input video data is written into the data buffer according to the input clock, and the output video data is read from the data buffer according to the output clock.

17. The method of claim 13, wherein the data buffer comprises a FIFO used for recording an input video data so as to output an output video data, a write pointer used for indicating a write address of the FIFO in which the input video data is recorded, and a read pointer used for indicating a read address of the FIFO in which the output video data is outputted; and the method further comprising the steps of:
setting the buffer status information according to the write pointer and the read pointer.

18. The method of claim 17, wherein the step of setting the buffer status information according to the write pointer and the read pointer comprises the steps of:
when the read pointer reaches to the write pointer, triggering an almost empty signal as the buffer status information, and tuning at least one of the first divisor and the second divisor in order to decrease a ratio of the second divisor to the first divisor; and
when the write pointer reaches to the read pointer, triggering an almost full signal as the buffer status information, and tuning at least one of the first divisor and the second divisor in order to increase the ratio of the second divisor to the first divisor.
